(19) United States
(12) Patent Application Publication
(10) Pub. No.: US 2024/0039470 A1
(43) Pub. Date: Feb. 1, 2024

(54) MODULAR MULTI-PANEL SOLAR CELL

(71) Applicant: Jonathan Jacques, Peabody, MA (US)

(72) Inventor: Jonathan Jacques, Peabody, MA (US)

(21) Appl. No.: 18/361,156

(22) Filed: Jul. 28, 2023

Related U.S. Application Data
(60) Provisional application No. 63/369,899, filed on Jul. 29, 2022.

(51) Int. Cl. H02S 40/36; H02S 40/22; H01L 31/05

(52) U.S. Cl. CPC H02S 40/36; H02S 40/22; H01L 31/0504

(57) ABSTRACT

Various solar panels and bifacial, solar panel assemblies are described. One solar panel includes a substrate having a first side and a second side opposite the first side. A first solar cell having a first orientation and a second solar cell having a second orientation disposed on the first side of the substrate are disposed on the first side of the substrate. The second orientation is different from the first orientation. An electrical conductor connecting the first solar cell and the second solar cell. The solar panel may be connected with other solar panels to form a bifacial, solar panel assembly.

### STATEMENT OF RELATED INVENTIONS

This application is a U.S. Nonprovisional application which claims the benefit of U.S. Provisional Application No. 63/369,899, filed Jul. 29, 2022, and is hereby incorporated by reference in its entirety.

### BACKGROUND

Various embodiments relate generally to solar panel systems and devices and, more specifically, relate to modular multi-panel solar cell.

This section is intended to provide a background or context. The description may include concepts that may be pursued, but have not necessarily been previously conceived or pursued. Unless indicated otherwise, what is described in this section is not deemed prior art to the description and claims and is not admitted to be prior art by inclusion in this section.

Solar panel systems have been described in various applications. Such applications include solar charged lamp posts, such as posts which include drone recharging stations. These applications include features of the pyramid wall system (PWS) described in U.S. Patent Publication 2022/0128205, published Apr. 28, 2022, as well as features found in U.S. Patent Publication 2020/0333571, published Oct. 22, 2020; and U.S. Pat. No. 10,707,807, issued Jul. 7, 2020; U.S. Pat. No. 9,929,691, issued Mar. 27, 2018, the disclosures of which are incorporated by reference herein in their entirety.

### SUMMARY

The below summary is merely representative and non-limiting.

The above problems are overcome, and other advantages may be realized, by the use of the embodiments.

In a first aspect, an embodiment provides a solar panel. The solar panel includes a substrate having a first side and a second side opposite the first side. A first solar cell having a first orientation and a second solar cell having a second orientation disposed on the first side of the substrate are disposed on the first side of the substrate. The second orientation is different from the first orientation. An electrical conductor connecting the first solar cell and the second solar cell.

In another aspect, an embodiment provides a bifacial, solar panel assembly. The bifacial, solar panel assembly incudes an upward-facing solar panel and a downward-facing solar panel. The upward-facing solar panel has an upward-facing substrate having an upward-facing side and a second side opposite the upward-facing side. A first upward-facing, solar cell having a first, upward-facing orientation is also disposed on the upward-facing side of the upward-facing substrate. The second, upward-facing orientation is different from the first, upward-facing orientation and the first, upward-facing solar cell is electrically connected to the second, upward-facing solar cell. The downward-facing solar panel has a downward-facing substrate having a downward-facing side and a second side opposite the downward-facing. A first downward-facing, solar cell having a first, downward-facing orientation and a second, downward-facing solar cell having a second, downward-facing orientation are disposed on the downward-facing side of the downward-facing substrate. The second, downward-facing orientation is different from the first, downward-facing orientation and the first, downward-facing solar cell is electrically connected to the second, downward-facing solar cell. The upward-facing solar panel is disposed with the second side of the upward-facing substrate is adjacent the second side of the downward-facing solar panel. Additionally, the upward-facing solar panel is electrically connected to the downward-facing solar panel.

In a further aspect, an embodiment provides solar panel array. The solar panel array includes two or more bifacial, solar panel assemblies and at least one reflector between the individual bifacial, solar panel assemblies.

### BRIEF DESCRIPTION OF THE DRAWINGS

Aspects of the described embodiments are more evident in the following description, when read in conjunction with the attached Figures.

FIG. 1A shows an embodiment of a multi-panel solar cell unit.

FIG. 1B shows another embodiment of a multi-panel solar cell unit.

FIG. 2 is a close-up view of part of a multi-panel solar cell unit.

FIG. 3A illustrates a stacked array of multi-panel solar cell units.

FIG. 3B illustrates an angled embodiment of the stacked array of FIG. 3A.

FIG. 4A illustrates a rhombus-shaped inverted pyramid.

FIG. 4B illustrates a profile of the rhombus-shaped inverted pyramid of FIG. 4A.

FIG. 5 shows a curved reflector from the stacked array of FIGS. 3A/3B.

FIG. 6 shows elements of the inverted pyramid of FIG. 5A.

FIG. 7 illustrates a solar panel array featuring various multi-panel solar cell units.

FIG. 8 illustrates an exploded view of the solar panel array of FIG. 7.

FIG. 9 shows a first multi-panel solar cell unit of FIG. 7.

FIG. 10 shows another multi-panel solar cell unit of FIG. 7.

FIG. 11 shows a first reflective element suitable for use in the solar panel array of FIG. 7.

FIG. 12 shows a side view of the reflective element of FIG. 11.

FIG. 13 shows another reflective element suitable for use in the solar panel array of FIG. 7.

FIG. 14 shows a side view of the reflective element of FIG. 13.

FIG. 15 demonstrates another solar panel unit.

FIG. 16 demonstrates a further solar panel unit.

FIG. 17 illustrates a close-up view of a support structure suitable for use in the solar panel array of FIG. 7.

FIG. 18 shows a rhombus assembly with multiple solar panel arrays.

FIG. 19 shows the rhombus assembly of FIG. 18 without the multiple solar panel arrays.

FIG. 20 shows another view of the rhombus assembly of FIG. 18.

### DETAILED DESCRIPTION

Various embodiments provide a multi-panel solar cell unit. By combining multiple smaller solar panels in an array, it is possible to generate more energy. Such results are caused by more than just increasing the area in which energy is collected with the addition of various features, for example, by careful arranging the individual panels, by providing gaps between the individual panels, etc.

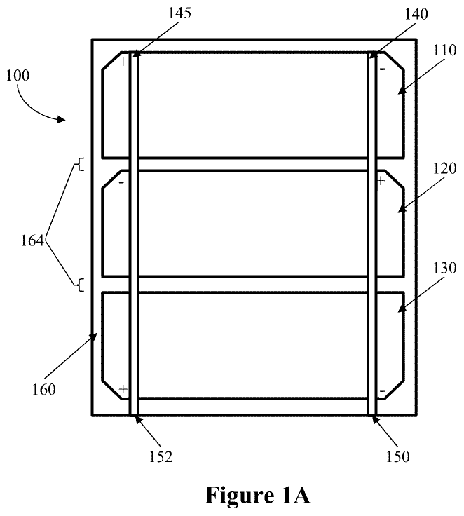

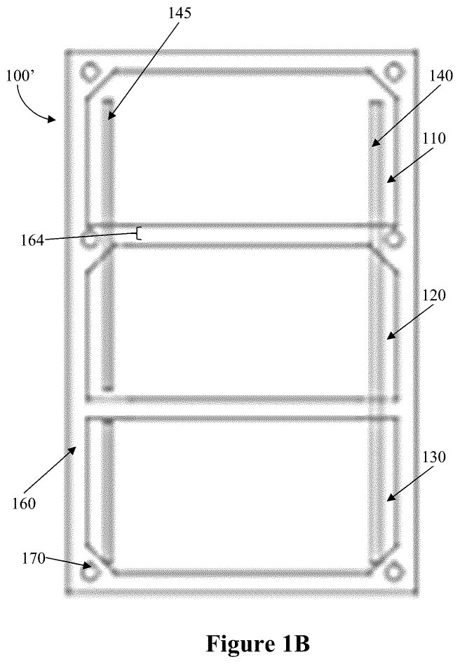

FIG. 1A shows an embodiment of a multi-panel solar cell unit 100. The unit 100 includes three separate solar cells 110, 120, 130 (which may be half-cells). These cells 110, 120, 130 are electrically connected by conductor ribbons 140 and 145. At the base of the unit 100, the conductors 140 and 145 may include connection points 150, 152 which may be configured to be attached to another element, for example, using screws, friction fit connectors, etc.

As shown, the cells 110, 120, 130 are arranged so that cells 110 and 120 have their notches directed to the same edge (up or away from the connection points 150, 152) and cell 130 has its notches directed to the edge with the connection points 150, 152 (down).

Additionally, cells 110 and 130 are oriented so that the positive connection (+) is on the right side of the unit 100.

The multi-panel solar cell unit 100 includes a casing material 160, such as glass or laminate. This material 160 is at least partially translucent to visible and/or infrared (IR) light. Gaps 164 between the cells 110, 120, 130 allow light to travel through the unit 100.

In some non-limiting embodiments, the material 160 may include a treatment, coating or film which amplifies light in the IR spectrum, for example, by converting high-frequency blue light into lower frequency red (or IR) light.

While shown as individual elements, the conductor ribbons 140 and 145 may be made of small sub-sections and may (or may not) include gaps within the length of the conductor ribbon 140 and 145.

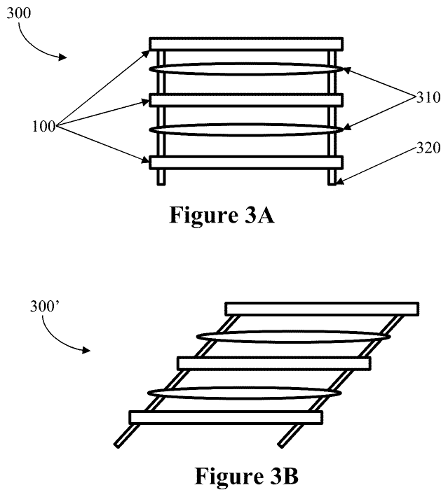

FIG. 1B shows another embodiment of a multi-panel solar cell unit 100′. As with unit 100, unit 100′ also includes material 160, cells 110, 120, 130, conductor ribbons 140, 145 and gaps 164. In addition, unit 100′ has openings 170 which may be used to secure the unit 100′ to a frame or within an array (such as shown in FIG. 3).

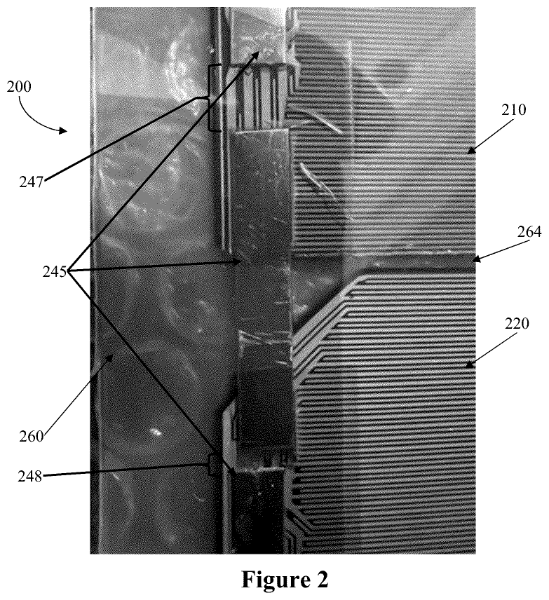

FIG. 2 is a close-up view of part of a multi-panel solar cell unit 200. The unit 200 shows two of the three solar cells 110, 120. The cells are secured in material 160 and between the cells 110, 120 is a gap 164. Ribbon 145 provides a conductive path for energy generated by the cells 110, 120. There are gaps 247, 248 in the ribbon 145 where electricity may travel through conductive paths within the cells 110, 120.

FIG. 3A illustrates a stacked array 300 of multi-panel solar cell units 100. The array 300 includes three units 100 which are separated by reflectors 310. The array 300 also includes posts 320 which hold the units 100 and reflectors 310.

Each reflector 310 is configured to reflect light in a spectrum which can be absorbed by the units 100. The reflectors 310 have curved upper and lower surfaces and may also include opening through which the posts 320 may extend. See FIG. 5.

In some embodiments, the reflectors 310 are chrome plated and/or include a treatment, coating or film which amplifies light in the IR spectrum.

The posts 320 secure the units 100 and reflectors 310 in position. Additionally, one or more of posts 320 may provide a conductive connection so that energy collected by the units 100 may be transmitted from the array 300.

FIG. 3B illustrates a stacked array 300′ which is positioned at an angle. As shown, the stacked array 300 is stacked at an angle, θ, such that the element above is offset and does not fully cover the element below it. In some embodiments θ may be between 150 and 30°, such as 22.5°.

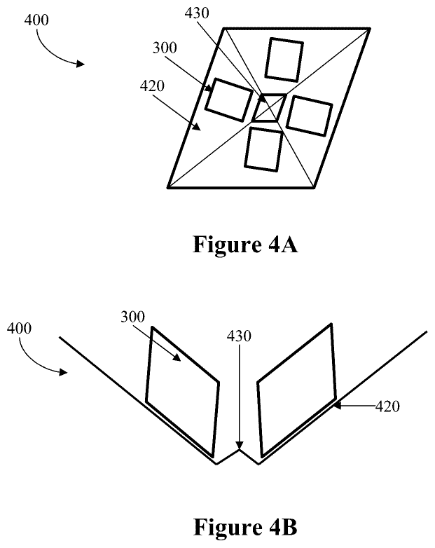

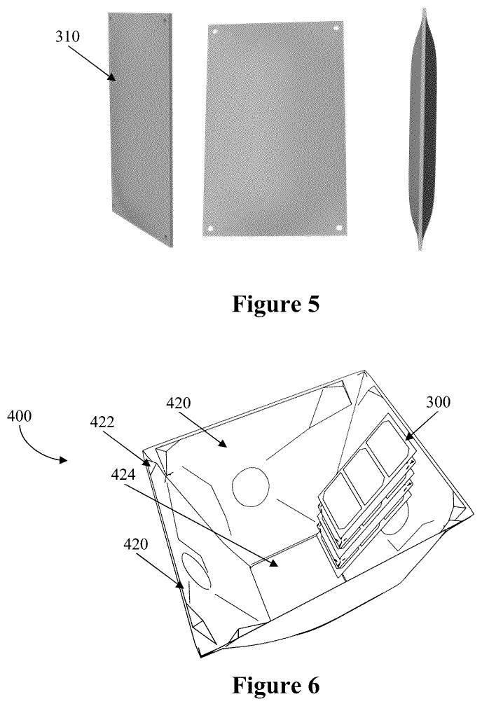

FIG. 4A illustrates a rhombus-shaped inverted pyramid 400 and FIG. 4B illustrates a profile of the rhombus-shaped inverted pyramid 400. The inverted pyramid 400 includes four sides 420 and the footprint of the inverted pyramid 400 is rhombus shaped.

In alternative embodiments, there may be more of less sides, such as 3 or 5. In such situations, the footprint would be differently shaped, e.g., a triangle or pentagon.

Attached to each of the sides 420 is a stacked array 300. The surfaces of the sides 420 are configured to reflect light in a spectrum which can be absorbed by the units 100. In some embodiments, the sides 420 are chrome plated and/or include a treatment, coating or film which amplifies light in the IR spectrum. The sides 420 may also include opening through which the posts 320 may extend and be secured.

In some embodiments, such as shown in FIG. 6, the sides 420 of the inverted pyramid 400 include extensions 422 which are configured to reflect light within the inverted pyramid 400 so as to be directed at the stacked arrays 300. Additionally, the sides 420 create an opening 424 so that a pyramidal reflect 430 may be positioned within the inverted pyramid 400.

In an alternative embodiment, the pyramidal reflect 430 may be formed by the sides 420.

As shown, the stacked array 300 covers a portion of the side 420 to which it is connected.

A cover (not shown) may be located over the inverted pyramid 400. The cover may be flat, dimpled, concave, convex or otherwise shaped. The cover may also include a treatment, coating or film which amplifies light in a given spectrum, such as IR.

The inverted pyramid 400 may include one or more opening which allow water or other liquids (or gases) to exit the inverted pyramid 400.

The inverted pyramid 400 may include one or more light producing elements, such as LEDs. The light producing elements may be configured to produce light in the IR spectrum and/or in a visible spectrum. In some embodiments, the LEDs may be located in the pyramidal reflect 430, in the sides 420 and/or in the reflectors 310.

In further embodiments, the inverted pyramid 400 may be located within a power generating wall, lamp post, or other structure. Each inverted pyramid 400 may be connected to an energy collecting element, such as a rechargeable battery or capacitor.

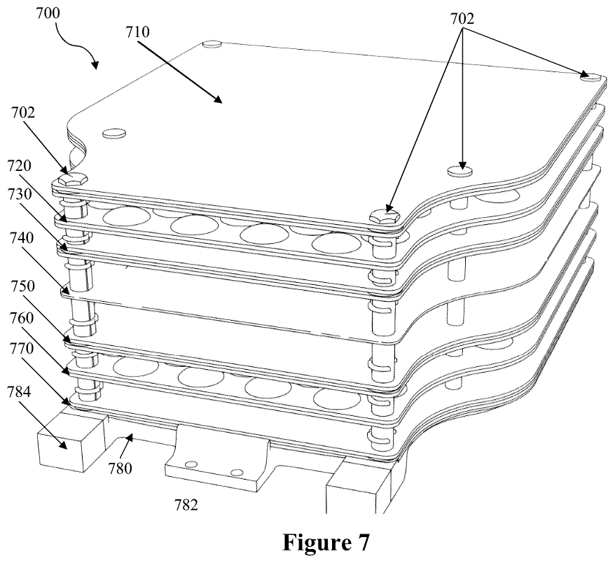

FIG. 7 illustrates a solar panel array 700 featuring various multi-panel solar cell units 710, 730, 750, 770. The array 700 features supporting elements (with spacers) 702 which hold the various elements. The top layer is a bifacial photovoltaic panel 710 having multiple cells (as shown below). The panel 710 is bifacial and is capable of collecting energy from both sides. Below the panel 710 is a small bubble reflector 720 which separates is from the bifacial photovoltaic panel 730.

Next in the array 700 is a large bubble reflector 740 and bifacial photovoltaic panel 750. As shown here, there is a larger separation between the large bubble reflector 740 and the adjacent photovoltaic panels 730, 750 than the separation between the small bubble reflector 720 and its adjacent photovoltaic panels 710, 730. In an alternative embodiment, this spacing may be identical.

Below the bifacial photovoltaic panel 750 is a second small bubble reflector 760 and bifacial photovoltaic panel 770. A bottom frame 780 provides a base for the supporting elements 702 which in turn hold the various elements 710-770. The bottom frame 780 also includes a connector for securing the array 700. Electrical connections 784 allow electricity generated by the various multi-panel solar cell units 710, 730, 750, 770 to be connected to an electrical circuit, for example, for collection by a battery or super-capacitor.

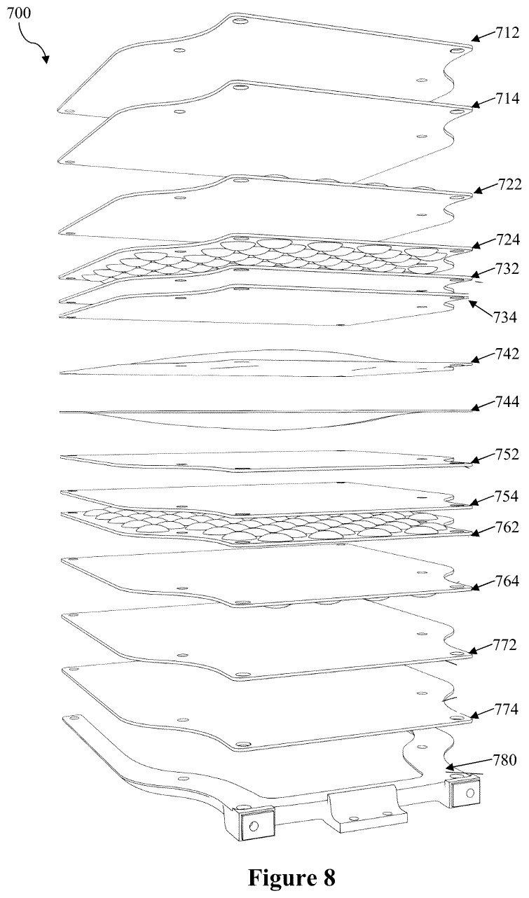

FIG. 8 illustrates an exploded view of the solar panel array 700 of FIG. 7. In this embodiment, various components have two opposite facing elements placed back-to-back. The multi-panel solar cell units 710, 730, 750, 770 include upward-facing panels 712, 732, 752, 772 and downward-facing panels 714, 734, 754, 774.

Likewise, the reflectors 720, 740 and 760 are made of two panels. Small bubble reflectors 720, 760 include upward-facing small bubble reflector 722, 762 and downward-facing small bubble reflector 724, 764. Large bubble reflector 740 is made of upward-facing large bubble reflector 742 and downward-facing large bubble reflector 744.

In further embodiments, various sub-elements may be fused together or otherwise connected. In other embodiments, the sub-elements may be disposed in such a way to leave a small gap between them (e.g., to allow heat to escape). In some embodiments, such spacing may be built into the element such that it defines various air passages through the element.

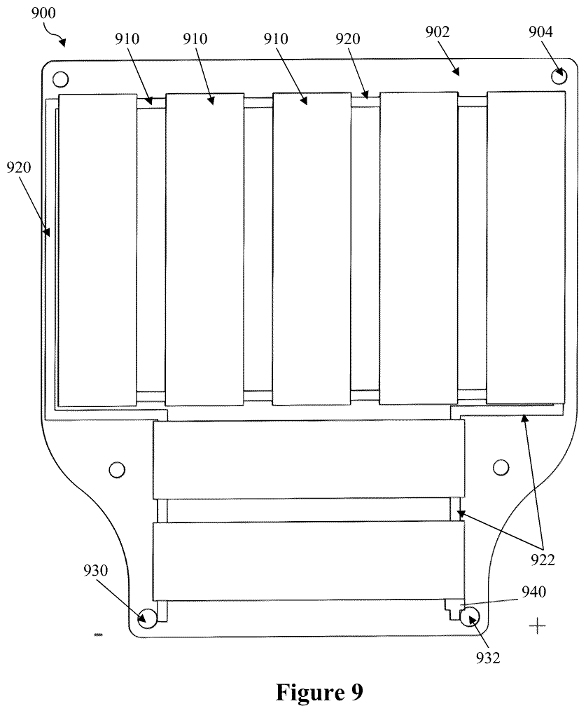

FIG. 9 shows a first multi-panel solar cell unit 900 suitable for use in the array 700 of FIG. 7. The unit 900 features a substrate 902 which holds multiple photovoltaic cells 910 (shown here with 7 cells 910). The cells 910 are connected in series by ribbon elements 920. The substrate 902 also includes openings 904 and connectors 930, 932. Like openings 904, connectors 930, 932 allow the substrate to be mounted, for example, by passing a screw through; however, connectors 930, 932 are also electrically connected to the photovoltaic cells 910 by ribbons 920.

Various electrical elements may be included on the multi-panel solar cell unit 900. As shown, a diode 940 is located adjacent to the positive connector 932. Additional electronic components may be used to improve charging behavior and provide additional functions, for example, a capacitor, and/or an IR LED.

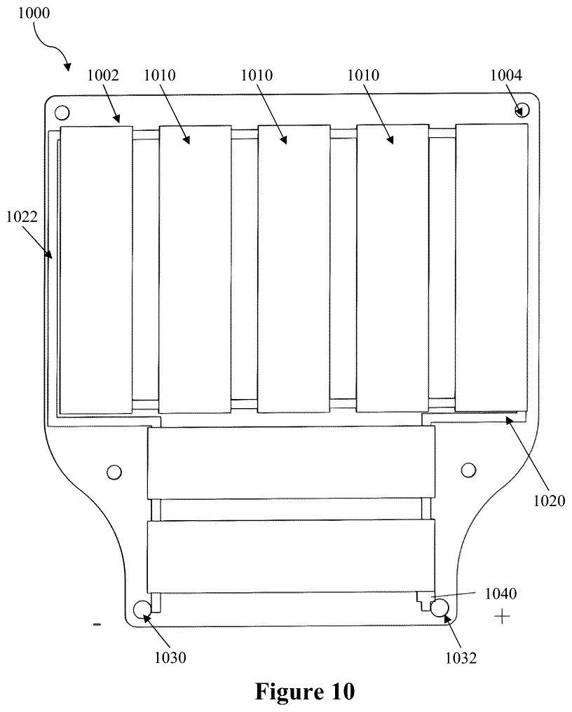

FIG. 10 shows another multi-panel solar cell unit 1000 suitable for use in the array 700 of FIG. 7. The panel 1000 has a substrate 1002 which holds the various photovoltaic cells 1010. The cells 1010 are electrically connected in parallel by ribbon 1020 connected to the negative side and ribbon 1022 connected to the positive side. Substrate 1002 also includes openings 904 which may be used for support. As shown, ribbon 1022 is also connected to a diode 1040. Negative connector 1030 and positive connector 1032 are electrically connected to the photovoltaic cells 1010.

Two multi-panel solar cell unit 900, 1000 may be combined into a single element, such as multi-panel solar cell unit 710. The combined units 900, 1000 can be sandwiched together back-to-back such that one is upward-facing and the other is downward-facing. The combined units 900, 1000 may be combined so that both are the same type of cell (e.g., both are units 900 or both are units 1000) or so that one of each unit 900, 1000 is used.

The units 900, 1000 may also be inverted (e.g., as a mirror-reflection) so that when the units are pressed back-to-back connectors 930, 932, 1030, 1032 line-up as both negative or both positive as desired, e.g., to connect the units 900, 1000 in parallel). Alternative, the units 900, 1000 may be lined up so that connectors 930, 932, 1030, 1032 line-up with their opposites (e.g., negative with positive) so that the units 900, 1000 may be connected in series.

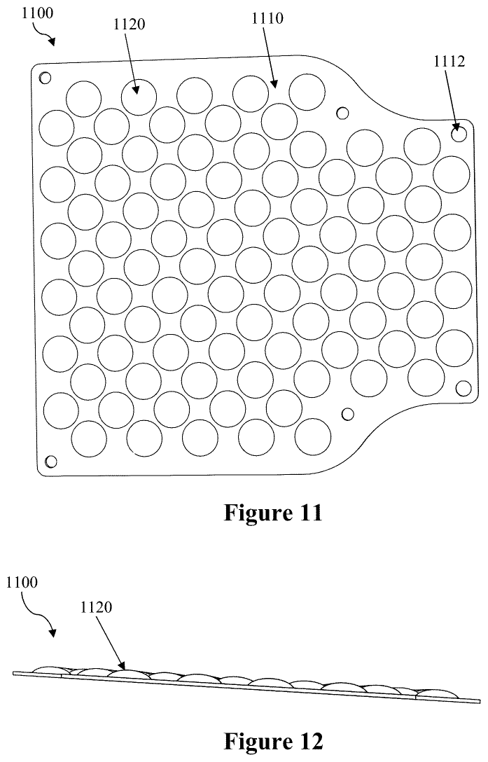

FIGS. 11 and 12 show a reflective element 1100 suitable for use as small bubble reflectors 720, 760 in FIG. 7. The reflective element 1100 has a reflective surface 1110 which serves to reflect light for energy generation. The reflective surface 1110 includes various raised bubbles 1120 which are shown in FIG. 12 as a side view. The reflective element 1100 also includes various openings 1112 that can be used to help mount the small reflective element 1100 in an array.

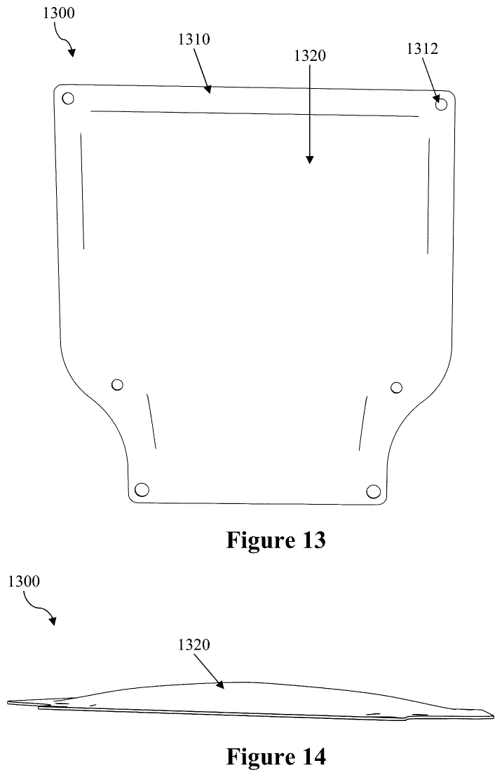

FIG. 13 shows another reflective element 1300 and FIG. 14 shows a side view of the reflective element 1300. The reflective element 1300 is a large bubble reflector and may be used as the large bubble reflector 740 shown in FIG. 7. The reflective element 1300 features a large, central bulge 1320. A reflective surface 1310 serves to reflect light incident upon the reflective element 1300 and openings 1312 can be used to mount the reflective element 1300.

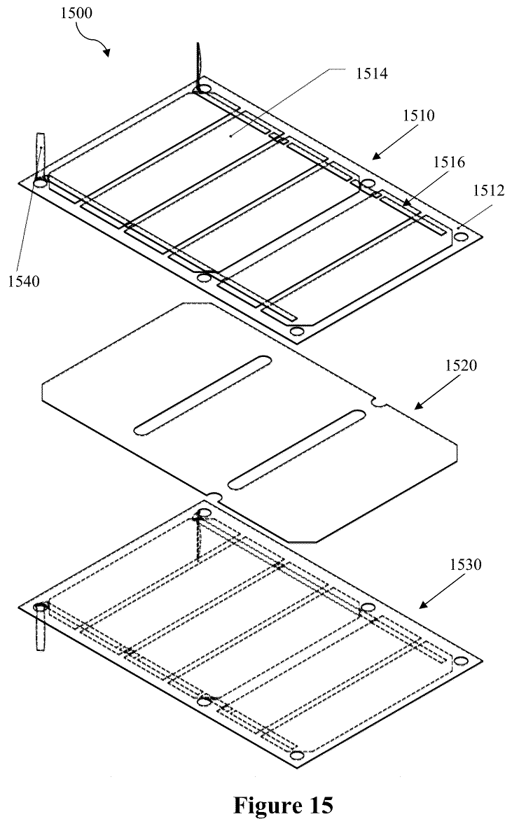

FIG. 15 demonstrates a solar panel unit 1500 having a rectangular outline. The solar panel unit 1500 is a bifacial panel capable of collecting energy from either the upward-facing cells 1514 and the downward facing cells 1514. The top solar panel 1510 includes a substrate 1512 (which may be transparent or reflective). The substrate 1512 supports a plurality of photovoltaic cells 1514 which are electrically connected by conductive ribbons 1516. The photovoltaic cells 1514 may be connected in series (as shown) or in parallel. A lead 1540 provides an electrical connection to the photovoltaic cells 1514.

Bottom solar panel 1530 is similar to top solar panel 1510 except it is facing the opposite (down-ward) direction. Between these solar panels 1510, 1530 is an insulator 1520.

In alternative embodiments, the bottom solar panel 1530 and top solar panel 1510 may be different (e.g., one may have cells 1510 connected in series while the other has have cells 1510 connected in parallel). Additionally, the solar panel unit 1500 may omit the insulator 1520.

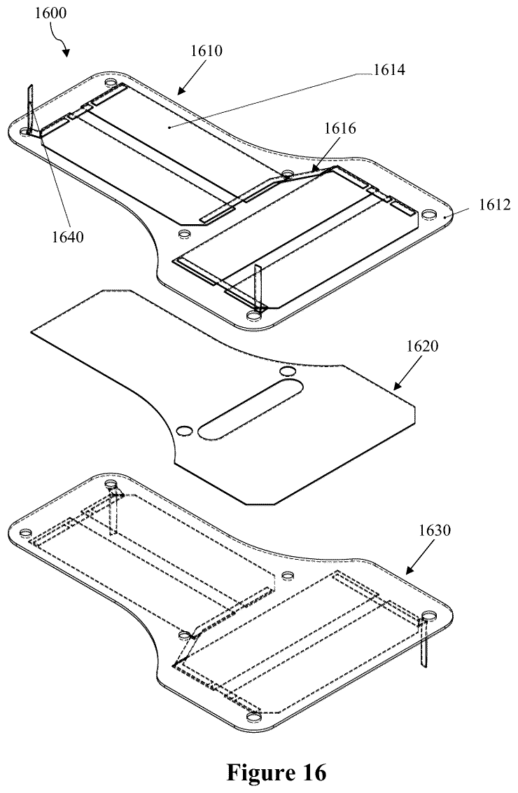

FIG. 16 demonstrates a solar panel unit 1600 having a T-shaped outline. Like the solar panel unit 1500, solar panel unit 1600 is also bifacial. The top solar panel 1610 includes a substrate 1612 and multiple photovoltaic cell 1614 connected together by conductive ribbons 1616 and to the leads 1640. A similar bottom solar panel 1630 is separated from the top solar panel 1610 by insulator 1620.

Various components, for example, reflective elements 1100, 1300 may have a vapor treatment or other such coating. The coating can alter the frequency of the light traveling through it such as to a frequency to which the photovoltaic cells are more reactive. On reflective surfaces, the treatment may work on the light twice, once when entering and then again after reflection.

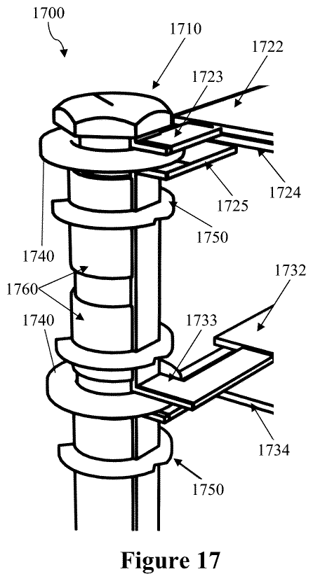

FIG. 17 illustrates a close-up view of a support structure 1700 suitable for use in the solar panel array of FIG. 7. The support structure 1700 includes a screw 1710 which is used to hold various panels 1722, 1724, 1732, 1734 and other elements (not shown here) such as reflectors 720, 740, 760. The screw 1710 may be connected to a frame element (not shown) such as bottom frame 780.

Spacing between elements is provided by washers 1740 and spacers 1760. A washers 1740 provides spacing between back-to-back panels, such as panels 1722, 1724. Spacers 1760 can provide support between elements which are further apart, such as, between panels 1722, 1724, 1732, 1734 and other elements (not shown here) such as reflectors 720, 740, 760. The washers 1740 and spacers 1760 may be non-conductive in order to allow panels 1722, 1724, 1732, 1734 to be electrically connected in different ways, e.g., in series or in parallel.

As shown, the panels 1722, 1724, 1732, 1734 are connected in series, with lead 1725 of downward-facing panel 1724 in contact with lead 1733 of upward-facing panel 1732. These leads 1725, 1733 are held in place by clips 1750. Additionally, spacers 1760 electrically isolate the leads 1725, 1733 from the screw 1710. In some embodiments, the screw 1710 may be coated with a non-conductive coating to help further electrically isolate the elements. In this arrangement, lead 1723 is electrically connected to the screw 1710 which provides an electrical path back to the frame element.

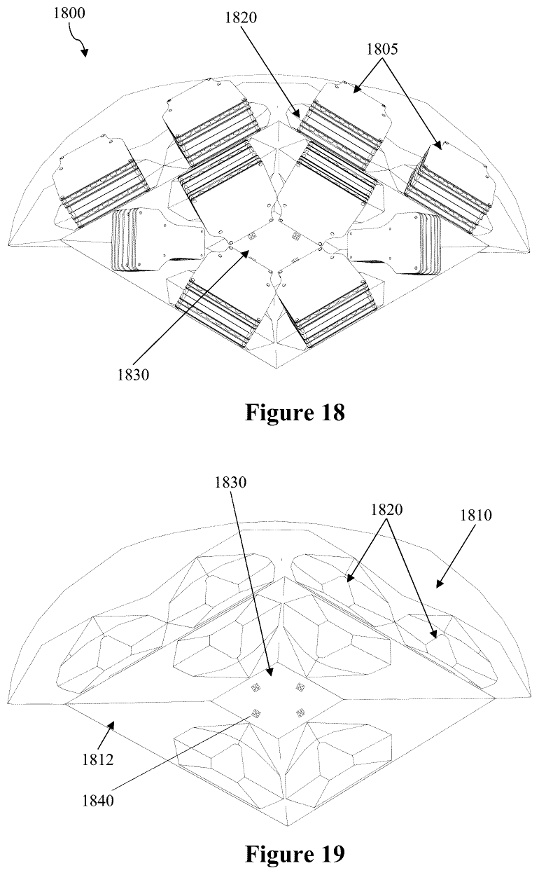

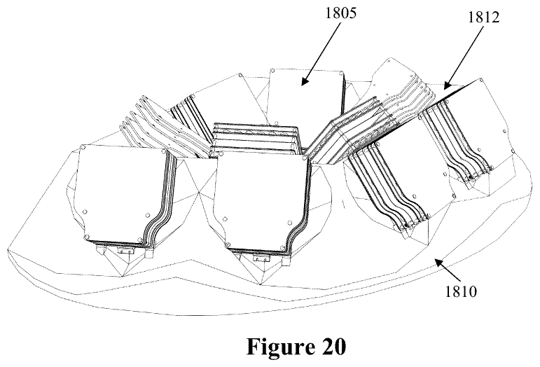

FIGS. 18-20 show a rhombus assembly 1800 for use with multiple solar panel arrays 1805. FIGS. 18 and 20 show the rhombus assembly 1800 from different views and FIG. 19 shows the rhombus assembly 1800 without the multiple solar panel arrays 1805.

As shown, the rhombus assembly 1800 has various solar panel arrays 1805 mounted on its surface over a reflective indentation 1820. There is an outer side 1810 and an inner side 1812. The inner side 1812 is sloped downward around a central pyramid 1830. Located on the central pyramid 1830 are various LED units 1840.

The outer side 1810 and the inner side 1812 may also be reflective as may be the central pyramid 1830. The reflective surfaces may include a treatment, coating or film which amplifies light traveling through the coating, for example, taking the blue 450 nanometer light and turning it to 850 nanometer light in the IR, by converting high-frequency blue light into lower frequency red (or IR) light, etc.

The LED units 1840 may include multiple individual LEDs. Each individual LED can produce light in a given spectrum. The individual LEDs can be selected so that their spectra overlap (e.g., all have the same profile) or so that the spectra has multiple peaks at different wavelengths. Additionally, the solar panel arrays 1805 may have individual solar panels which react differently to the wavelength and may be chosen so as to be more responsive to the peak wavelengths produced by the LED units 1840.

The foregoing description has been directed to particular embodiments. However, other variations and modifications may be made to the described embodiments, with the attainment of some or all of their advantages. Modifications to the above-described systems and methods may be made without departing from the concepts disclosed herein. Accordingly, the invention should not be viewed as limited by the disclosed embodiments. Furthermore, various features of the described embodiments may be used without the corresponding use of other features. Thus, this description should be read as merely illustrative of various principles, and not in limitation of the invention.

What is claimed is:

1. A solar panel comprising:
a substrate having a first side and a second side opposite the first side;
a first solar cell having a first orientation disposed on the first side of the substrate;
a second solar cell having a second orientation disposed on the first side of the substrate, wherein the second orientation is different from the first orientation; and
an electrical conductor connecting the first solar cell and the second solar cell.

2. The solar panel of claim 1, further comprising a diode electrically connected to the first solar cell.

3. The solar panel of claim 1, further comprising an electrical lead electrically connected to the first solar cell.

4. The solar panel of claim 1, wherein the first solar cell is connected in series with the second solar cell.

5. The solar panel of claim 1, wherein the first solar cell is connected in parallel with the second solar cell.

6. The solar panel of claim 1, wherein the second orientation is rotated 90° from the first orientation.

7. The solar panel of claim 1, wherein the second orientation is rotated 180° from the first orientation.

8. The solar panel of claim 1, wherein the second orientation is an inverse reflection of the first orientation.

9. A bifacial, solar panel assembly comprising:
an upward-facing solar panel comprising:
an upward-facing substrate having an upward-facing side and a second side opposite the upward-facing side;
a first upward-facing, solar cell having a first, upward-facing orientation disposed on the upward-facing side of the upward-facing substrate; and
a second, upward-facing solar cell having a second, upward-facing orientation disposed on the upward-facing side of the upward-facing substrate,
wherein the second, upward-facing orientation is different from the first, upward-facing orientation; and wherein the first, upward-facing solar cell is electrically connected to the second, upward-facing solar cell; and
a downward-facing solar panel comprising:
a downward-facing substrate having a downward-facing side and a second side opposite the downward-facing side;
a first downward-facing, solar cell having a first, downward-facing orientation disposed on the downward-facing side of the downward-facing substrate; and
a second, downward-facing solar cell having a second, downward-facing orientation disposed on the downward-facing side of the downward-facing substrate,
wherein the second, downward-facing orientation is different from the first, downward-facing orientation; and wherein the first, downward-facing solar cell is electrically connected to the second, downward-facing solar cell,
wherein the upward-facing solar panel is disposed with the second side of the upward-facing substrate is adjacent the second side of the downward-facing solar panel, and
wherein the upward-facing solar panel is electrically connected to the downward-facing solar panel.

10. The bifacial, solar panel assembly of claim 9, wherein the upward-facing solar panel and the downward-facing solar panel are disposed with a gap between the second side of the upward-facing substrate and the second side of the downward-facing solar panel.

11. The bifacial, solar panel assembly of claim 9, wherein the upward-facing solar panel and the downward-facing solar panel are connected in series.

12. The bifacial, solar panel assembly of claim 9, wherein the upward-facing solar panel and the downward-facing solar panel are connected in parallel.

13. A solar panel array comprising:
a plurality of bifacial, solar panel assemblies; and
at least one reflector disposed between the individual bifacial, solar panel assemblies.

14. The solar panel array of claim 13, wherein the plurality of bifacial, solar panel assemblies are connected in series.

15. The solar panel array of claim 13, wherein the plurality of bifacial, solar panel assemblies are connected in parallel.

16. The solar panel array of claim 13, wherein the at least one reflector comprises a large bubble reflector having a single large bulge and wherein the large bubble reflector has a coating configured to alter the frequency of light traveling through the coating.

17. The solar panel array of claim 13, wherein the at least one reflector comprises a small bubble reflector having a plurality of small bulges and wherein the small bubble reflector has a coating configured to alter the frequency of light traveling through the coating.

18. The solar panel array of claim 13, wherein the at least one reflector comprises:
a large bubble reflector having a single large bulge; and
a small bubble reflector having a plurality of small bulges.

19. The solar panel array of claim 13, wherein the plurality of bifacial, solar panel assemblies and the at least one reflector are disposed in an angled stack.

20. The solar panel array of claim 13, wherein the plurality of bifacial, solar panel assemblies and the at least one reflector are disposed in a vertical stack.

21. The solar panel array of claim 13, further comprising a frame element configured to secure the solar panel array.

22. The solar panel array of claim 19, further comprising a plurality of support elements configured to hold the plurality of bifacial, solar panel assemblies and the plurality of reflectors,
wherein the support elements provided electrical connections between the plurality of bifacial, solar panel assemblies and the frame element.
